(19) United States
(12) Patent Application Publication
(10) Pub. No.: US 2025/0069971 A1
(43) Pub. Date: Feb. 27, 2025

(54) SEMICONDUCTOR PACKAGE

(71) Applicant: Samsung Electronics Co., Ltd., Suwon-si (KR)

(72) Inventors: Yong Hoe CHO, Suwon-si (KR); Oh Guk KWON, Suwon-si (KR); Sun Jae KIM, Suwon-si (KR); Hui Yeong JANG, Suwon-si (KR)

(21) Appl. No.: 18/623,293

(22) Filed: Apr. 1, 2024

(30) Foreign Application Priority Data
Aug. 21, 2023 (KR) 10-2023-0108916

(51) Int. Cl. H01L 23/31; H01L 23/00; H01L 23/48; H01L 25/065

(52) U.S. Cl. CPC H01L 23/31; H01L 23/481; H01L 24/16; H01L 24/32; H01L 24/73; H01L 25/0657; H01L 2224/16145; H01L 2224/32145; H01L 2224/73204; H01L 2225/06513; H01L 2225/06568; H01L 2924/1431; H01L 2924/1815

(57) ABSTRACT

A semiconductor package comprises a first semiconductor chip, a second semiconductor chip on the first semiconductor chip, at least one connection bump between the first semiconductor chip and the second semiconductor chip, an underfill in a region below the second semiconductor chip and on a side of the at least one connection bump and a molding layer on the first semiconductor chip and on a side of the second semiconductor chip, wherein an upper surface of the second semiconductor chip is above an upper surface of the molding layer, a height difference between the upper surface of the second semiconductor chip and the upper surface of the molding layer is 0.3 μm to 2.0 μm, and a surface roughness of the upper surface of the second semiconductor chip is 3 nm or less.

### CROSS-REFERENCE TO RELATED APPLICATION

This application claims priority under 35 U.S.C. 119 to Korean Patent Application No. 10-2023-0108916 filed on Aug. 21, 2023, in the Korean Intellectual Property Office, the contents of which are herein incorporated by reference in its entirety.

### BACKGROUND

### Technical Field

The present disclosure relates to a semiconductor package.

### Description of the Related Art

With the development of the electronics industry, the demands for high functionality, high-speed and miniaturization of electronic components have been increased. In response to this trend, a method of stacking and packaging various semiconductor chips on one package wiring structure or a method of stacking a package on another package may be used. For example, a package-in-package (PIP) type semiconductor package or a package-on-package (POP) type semiconductor package may be used. Meanwhile, with miniaturization and a thin profile of the semiconductor package, cracks may easily occur in the semiconductor package due to external impact.

### BRIEF SUMMARY

Some embodiments of the present disclosure may provide a semiconductor package in which reliability of a product is improved.

Some embodiments of the present disclosure may provide a method for fabricating a semiconductor package, in which a semiconductor package having improved reliability of a product may be fabricated.

Potential advantages of the present disclosure are not limited to those mentioned above and additional advantages of the present disclosure, which are not mentioned herein, will be clearly understood by those skilled in the art from the following description of the present disclosure.

According to some aspects of the present inventive concept, a semiconductor package comprises a first semiconductor chip, a second semiconductor chip on the first semiconductor chip, at least one connection bump between the first semiconductor chip and the second semiconductor chip, an underfill in a region below the second semiconductor chip and on a side of the at least one connection bump and a molding layer on the first semiconductor chip and on a side of the second semiconductor chip, wherein an upper surface of the second semiconductor chip is above an upper surface of the molding, a height difference between the upper surface of the second semiconductor chip and the upper surface of the molding layer is 0.3 μm to 2.0 μm, and a surface roughness of the upper surface of the second semiconductor chip is 3 nm or less.

According to some aspects of the present inventive concept, a semiconductor package comprises a first semiconductor chip, a second semiconductor chip on the first semiconductor chip and a molding layer on the first semiconductor chip and on a side of the second semiconductor chip, wherein an upper surface of the second semiconductor chip is above an upper surface of the molding layer by 0.3 μm to 2.0 μm.

According to some aspects of the present inventive concept, a semiconductor package comprises a first semiconductor chip, a second semiconductor chip on the first semiconductor chip and a molding layer on the first semiconductor chip and on a side of the second semiconductor chip, wherein the second semiconductor chip includes a first portion that overlaps the molding layer and a second portion that is on the first portion and does not overlap the molding layer, and an upper surface of the molding layer is lower than an upper surface of the second semiconductor chip.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is a view illustrating a semiconductor package according to some embodiments.

FIG. 2 is an enlarged view illustrating a portion P1 of FIG. 1.

FIG. 3 is a view illustrating a semiconductor package according to some other embodiments.

FIG. 4 is an enlarged view illustrating a portion P2 of FIG. 3.

FIG. 5 is a view illustrating a semiconductor package according to some other embodiments.

FIG. 6 is an enlarged view illustrating a portion P3 of FIG. 5.

FIG. 7 is a view illustrating a semiconductor package according to some other embodiments.

FIG. 8 is a view illustrating a semiconductor package according to some other embodiments.

FIGS. 9 to 13 are views illustrating intermediate steps to describe a method for fabricating a semiconductor package according to some embodiments.

### DETAILED DESCRIPTION OF THE DISCLOSURE

Hereinafter, the embodiments according to the technical spirits of the present disclosure will be described with reference to the accompanying drawings.

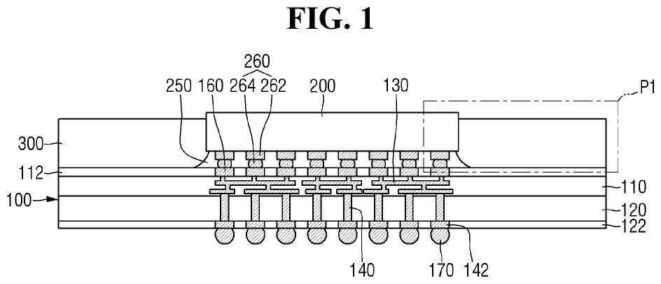

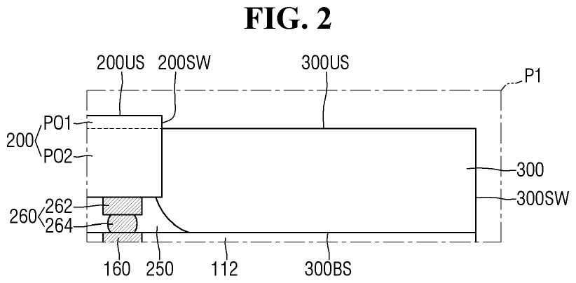

FIG. 1 is a view illustrating a semiconductor package according to some embodiments. FIG. 2 is an enlarged view illustrating a portion P1 of FIG. 1.

Referring to FIG. 1 and FIG. 2, the semiconductor package according to some embodiments may include a first semiconductor chip 100, a second semiconductor chip 200 and a molding layer 300.

The first semiconductor chip 100 and the second semiconductor chip 200 may be logic chips or memory chips. Each of the first semiconductor chip 100 and the second semiconductor chip 200 may be a logic chip. For example, each of the first semiconductor chip 100 and the second semiconductor chip 200 may be an application processor.

The first semiconductor chip 100 and the second semiconductor chip 200 may be the same type of memory chips. For example, the first semiconductor chip 100 and the second semiconductor chip 200 may be volatile memory chips such as a Dynamic Random Access Memory (DRAM) or a Static Random Access Memory (SRAM). For another example, the first semiconductor chip 100 and the second semiconductor chip 200 may be non-volatile memory chips such as a phase-change RAM (PRAM), a Magnetoresistive RAM (MRAM), a FerroelectricRAM (FeRAM) or a Resistive RAM (RRAM). For other example, the first semiconductor chip 100 and the second semiconductor chip 200 may be high bandwidth memories (HBM).

In addition, a portion of the first semiconductor chip 100 and the second semiconductor chip 200 may be a memory chip, and another portion of the first semiconductor chip 100 and the second semiconductor chip 200 may be a logic chip. For example, a portion of the first semiconductor chip 100 and the second semiconductor chip 200 may be a microprocessor, an analog device, a digital signal processor or an application processor.

The first semiconductor chip 100 may be below the second semiconductor chip 200. A width of the first semiconductor chip 100 may be greater than that of the second semiconductor chip 200.

The first semiconductor chip 100 may include a first semiconductor device layer 110, a first semiconductor substrate 120, a through via 140, a first lower connection pad 142, an upper passivation film 112, a lower passivation film 122, a first upper connection pad 160 and at least one first connection bump 170.

The first semiconductor device layer 110 may be on the first semiconductor substrate 120. The first semiconductor device layer 110 may include various kinds of individual devices and an inter-layer insulating film. The individual devices may include a variety of microelectronic devices, for example, a metal-oxide-semiconductor field effect transistor (MOSFET) such as a complementary metal-insulator-semiconductor (CMOS) transistor, a system large scale integration (LSI), a flash memory, a DRAM, an SRAM, an EEPROM, a PRAM, an MRAM, a RRAM, an image sensor such as a CMOS imaging sensor (CIS), a micro-electro-mechanical system (MEMS), an active device, a passive device and the like.

The individual devices of the first semiconductor device layer 110 may be electrically connected to a conductive region formed in the first semiconductor substrate 120. The individual devices of the first semiconductor device layer 110 may be electrically separated from other adjacent individual devices by insulating films. The first semiconductor device layer 110 may include a first wiring structure 130 electrically connecting at least two of the plurality of individual devices or the plurality of individual devices with the conductive region of the first semiconductor substrate 120.

The first semiconductor substrate 120 may be below the first semiconductor device layer 110. The first semiconductor substrate 120 may be, for example, a bulk silicon or a silicon-on-insulator (SOI). For another example, the first semiconductor substrate 120 may be a silicon substrate. For other example, the first semiconductor substrate 120 may include, but is not limited to, silicon germanium, silicon germanium on insulator (SGOI), indium antimonide, lead telluride, indium arsenide, indium phosphide, gallium arsenide or gallium antimonide.

The first semiconductor substrate 120 may include a conductive region, for example, a well doped with impurities or a structure doped with impurities. The first semiconductor substrate 120 may have various device isolation structures such as a shallow trench isolation (STI) structure.

The upper passivation film 112 and the first upper connection pad 160 may be formed on an upper surface of the first semiconductor device layer 110. The upper passivation film 112 may be on or cover the upper surface of the first semiconductor device layer 110, and may expose the first upper connection pad 160. The upper passivation film 112 may include, for example, a photoimageable dielectric (PID) material, but is not limited thereto.

The upper passivation film 112 may be on the first semiconductor device layer 110. The upper passivation film 112 may protect the first wiring structure 130 and other structures in the first semiconductor device layer 110 from external impact or moisture. The first upper connection pad 160 may be in the upper passivation film 112. The upper passivation film 112 may expose a portion of an upper surface of the first upper connection pad 160.

The lower passivation film 122 may be below the first semiconductor substrate 120. The lower passivation film 122 may protect the through via 140 and other structures in the first semiconductor substrate 120 from external impact or moisture. The first lower connection pad 142 may be in the lower passivation film 122. The lower passivation film 122 may expose a portion of an upper surface of the first lower connection pad 142.

In some embodiments, the first upper connection pad 160 may be electrically connected to the first lower connection pad 142. For example, the first upper connection pad 160 may be electrically connected to the first lower connection pad 142 through the first wiring structure 130 and the through via 140.

The through via 140 may pass through the first semiconductor substrate 120. The through via 140 may extend from the upper surface of the first semiconductor substrate 120 toward a lower surface of the first semiconductor substrate 120. The through via 140 may be connected to the first wiring structure 130 provided in the first semiconductor device layer 110.

The through via 140 may be on the first lower connection pad 142. The through via 140 may be in contact with the first lower connection pad 142. The through via 140 may be connected to the first connection bumps 170. The first semiconductor substrate 120, which includes the through via 140, may be spaced apart from the second semiconductor chip 200 with the first semiconductor device layer 110 interposed therebetween. The first semiconductor substrate 120 may be farther away from the second semiconductor chip 200 than the first semiconductor device layer 110. The through via 140 may be spaced farther apart from the second semiconductor chip 200 than the first wiring structure 130.

The through via 140 may include a barrier film formed on a surface of a pillar shape and a buried conductive layer filling the inside of the barrier film. The barrier film may include, but is not limited to, at least one of Ti, TiN, Ta, TaN, Ru, Co, Mn, WN, Ni or NiB. The buried conductive layer may include, but is not limited to, at least one of Cu, Cu alloy, such as CuSn, CuMg, CuNi, CuZn, CuPd, CuAu, CuRe and CuW, W, W alloy, Ni, Ru or Co.

In some embodiments, an insulating film may be interposed between the first semiconductor substrate 120 and the through via 140. The insulating film may include an oxide film a nitride film, a carbide film, a polymer or their combination, but is not limited thereto.

The first wiring structure 130 may include a metal wiring layer and a via plug. For example, the first wiring structure 130 may have a multi-layered structure in which two or more metal wiring layers or two or more via plugs are alternately stacked.

The first lower connection pad 142 may be in the lower passivation film 122. A lower surface of the first lower connection pad 142 may be exposed by or free from contact with the lower passivation film 122. The first lower connection pad 142 may be surrounded by the lower passivation film 122. That is, the passivation film 122 may be on a side or sides of the first lower connection pad. The first lower connection pad 142 may be below the first semiconductor substrate 120. The first lower connection pad 142 may be electrically connected to the through via 140 inside the first semiconductor substrate 120. The first lower connection pad 142 may be electrically connected to the first wiring structure 130 through the through via 140. The first lower connection pad 142 may include at least one selected from aluminum (Al), copper (Cu), nickel (Ni), tungsten (W), platinum (Pt) or gold (Au).

The first upper connection pad 160 electrically connected to the first wiring structure 130 may be formed on the upper surface of the first semiconductor device layer 110. The first upper connection pad 160 may be made of the same material as that of the first lower connection pad 142. The first upper connection pad 160 may be in the upper passivation film 112. The first upper connection pad 160 may be surrounded by the upper passivation film 112. That is, the upper passivation film 112 may be on a side or sides of the first upper connection pad 160. An upper surface of the first upper connection pad 160 may be exposed by or free from contact with the upper passivation film 112.

The first connection bumps 170 may be in contact with the first lower connection pad 142. The first connection bumps 170 may electrically connect the first semiconductor chip 100 to the outside. The first connection bumps 170 may receive at least one of a control signal, a power signal or a ground signal for the operation of the first semiconductor chip 100 from the outside. The first connection bumps 170 may receive a data signal or signals to be stored in the first semiconductor chip 100 from an external device. The first connection bumps 170 may provide data stored in the first semiconductor chip 100 to an external device. For example, each of the first connection bumps 170 may include a pillar structure, a ball structure or a solder layer. The first connection bumps 170 may be external connection bumps.

The second semiconductor chip 200 may be on the first semiconductor chip 100. For example, the second semiconductor chip 200 may be packaged on the upper surface of the first semiconductor chip 100. The second semiconductor chip 200 may have a width smaller than that of the first semiconductor chip 100.

The second semiconductor chip 200 may be an integrated circuit (IC) in which several hundreds to several millions of semiconductor devices are integrated in one chip. For example, the second semiconductor chip 200 may be, but is not limited to, an application processor (AP) such as a central processing unit (CPU), a graphic processing unit (GPU), a field-programmable gate array (FPGA), a digital signal processor, an encryption processor, a microprocessor and a microcontroller.

For another example, the second semiconductor chip 200 may be a logic chip such as an analog-digital converter (ADC) or an application-specific IC (ASIC), or may be a memory chip such as a volatile memory (e.g., DRAM) or a non-volatile memory (e.g., ROM or flash memory). In addition, the second semiconductor chip 200 may be configured by combination of the logic chip and the memory chip.

Although only a second semiconductor chip 200 is shown as being formed on the first semiconductor chip 100, this is only for convenience of description. For example, a plurality of semiconductor chips may be formed side by side on the first semiconductor chip 100, or a plurality of second semiconductor chips may be sequentially stacked on the first semiconductor chip 100.

In some embodiments, the second semiconductor chip 200 may be packaged on the first semiconductor chip 100 by a flip chip bonding method. For example, one or more second connection bumps 260 may be formed between the upper surface of the first semiconductor chip 100 and the lower surface of the second semiconductor chip 200. The second connection bumps 260 may electrically connect the first semiconductor chip 100 with the second semiconductor chip 200.

An upper surface 200US of the second semiconductor chip may be above an upper surface 300US of the molding layer. The upper surface 200US of the second semiconductor chip may be exposed by or free from contact with the upper surface 300US of the molding layer. That is, the upper surface 200US of the second semiconductor chip may not be covered by the molding layer 300. The upper surface 200US of the second semiconductor chip may protrude or extend farther in an upward direction than the upper surface 300US of the molding layer from a lower surface 300BS of the molding layer.

The second semiconductor chip 200 may include silicon (Si). Silicon (Si) may be exposed to the upper surface 200US of the second semiconductor chip.

The second semiconductor chip 200 may partially overlap the molding layer 300 and may not partially overlap the molding layer 300. The second semiconductor chip 200 may include a first portion PO1 that does not overlap the molding layer 300 and a second portion PO2 that overlaps the molding layer 300.

A side 200SW of the first portion PO1 of the second semiconductor chip 200 may not be covered by the molding layer 300. The side 200SW of the first portion PO1 may be exposed by or free from contact with the molding layer 300. The side 200SW of the second portion PO2 of the second semiconductor chip 200 may be covered by the molding layer 300. That is, the molding layer 300 may be on the side 200SW of the second portion PO2 of the second semiconductor chip 200. The side 200SW of the second portion PO2 may not be exposed by or free from contact with the molding layer 300.

The first portion PO1 of the second semiconductor chip 200 may be above the molding layer 300. The first portion PO1 of the second semiconductor chip 200 may be protruded from the upper surface 300US of the molding layer. The upper surface 200US of the second semiconductor chip 200 and the upper surface 300US of the molding layer may have a step difference.

For example, a height of the first portion PO1 may be 0.3 μm to 2.0 μm above the upper surface 300US of the molding layer. That is, the height from the upper surface 300US of the molding layer to an upper surface of the first portion PO1 may be 0.3 μm to 2.0 μm. A height of a sidewall of the first portion PO1 of the second semiconductor chip 200, which is exposed without being covered by the molding layer 300, may be 0.3 μm to 2.0 μm. The upper surface 200US of the second semiconductor chip 200 may be above the upper surface 300US of the molding layer 300 by as much as 0.3 μm to 2.0 μm. The upper surface 200US of the second semiconductor chip 200 may be more protruded than the upper surface 300US of the molding layer 300 by as much as 0.3 μm to 2.0 μm.

The upper surface 200US of the second semiconductor chip may have a surface roughness of 3 nm or less. For example, the surface roughness of the upper surface 200US of the second semiconductor chip may be 1.4 nm. A surface roughness refers to the average deviation from the mean height.

Each of the second connection bumps 260 may include, for example, a first pillar layer 262 and a first solder layer 264.

The first pillar layer 262 may be protruded from the lower surface of the second semiconductor chip 200. The first pillar layer 262 may include, for example, copper (Cu), a copper alloy, nickel (Ni), palladium (Pd), platinum (Pt), gold (Au), cobalt (Co) and their combination, but is not limited thereto.

The first solder layer 264 may connect the first pillar layer 262 with the first semiconductor chip 100. For example, the first solder layer 264 may be connected to the first upper connection pad 160. The first solder layer 264 may be, for example, spherical or elliptical, but is not limited thereto. The first solder layer 264 may include, for example, tin (Sn), indium (In), bismuth (Bi), antimony (Sb), copper (Cu), silver (Ag), zinc (Zn), lead (Pb) and their combination, but is not limited thereto.

An underfill 250 may be formed on the first semiconductor chip 100. The underfill 250 may fill a region between the first semiconductor chip 100 and the second semiconductor chip 200. The underfill 250 may fill a region below the second semiconductor chip 200. The underfill 250 may reduce damage or prevent the second semiconductor chip 200 from being broken by fixing the second semiconductor chip 200 onto the first semiconductor chip 100. The underfill 250 may cover or be on the second connection bumps 260. The underfill 250 may surround the second connection bumps 260. The underfill 250 may cover or be on a side or sides of the second connection bumps 260. The second connection bumps 260 may electrically connect the first semiconductor chip 100 with the second semiconductor chip 200 by passing through the underfill 250.

The underfill 250 may include, for example, an insulating polymer material such as an epoxy molding compound (EMC), but is not limited thereto. In some embodiments, the underfill 250 may include a material different from that of the molding layer 300 that will be described later. For example, the underfill 250 may include an insulating material that is more fluid than that of the molding layer 300. Therefore, the underfill 250 may efficiently fill a narrow space between the first semiconductor chip 100 and the second semiconductor chip 200.

The molding layer 300 may be formed on the first semiconductor chip 100. The lower surface 300BS of the molding layer may be on the same plane as the upper surface of the first semiconductor chip 100.

The molding layer 300 may cover the first semiconductor chip 100 and the second semiconductor chip 200 to protect the first semiconductor chip 100 and the second semiconductor chip 200. The molding layer 300 may have a side aligned with the first semiconductor chip 100. For example, a side 300SW of the molding layer may be on the same plane as that of the first semiconductor chip 100.

The molding layer 300 may cover the second semiconductor chip 200. The molding layer 300 may surround or be on a side or sides of the second semiconductor chip 200. The molding layer 300 may cover the side 200SW of the second semiconductor chip. The molding layer 300 may overlap a portion of the side of the second semiconductor chip 200 and may not overlap the other portion of the side of the second semiconductor chip 200. The molding layer 300 may cover a portion of the side 200SW of the second semiconductor chip and may not cover another portion of the side 200SW of the second semiconductor chip.

The molding layer 300 may cover the side of the second portion PO2 of the second semiconductor chip 200. The molding layer 300 may not cover the side of the first portion PO1 of the second semiconductor chip 200.

The molding layer 300 may not cover the upper surface 200US of the second semiconductor chip. The upper surface 300US of the molding layer may be below the upper surface of the second semiconductor chip 200. The molding layer 300 may not vertically overlap the second semiconductor chip 200. The molding layer 300 may not be in contact with the upper surface 200US of the second semiconductor chip.

The upper surface 300US of the molding layer may be flat or planar. Between the side of the first semiconductor chip 100 and the side of the second semiconductor chip 200, the height of the upper surface 300US of the molding layer may be constant as a distance from the upper surface of the first semiconductor chip 100 or the lower surface 300BS of the molding layer.

The molding layer 300 may include, for example, an insulating polymer material such as an epoxy molding compound (EMC). The molding layer 300 may include a thermosetting resin such as an epoxy resin, a thermoplastic resin such as polyimide, or a resin including a reinforcing material, such as a filler, in the thermosetting resin and the thermoplastic resin, for example, ABF, FR-4, BT resin, etc.

The filler may be at least one selected from a group consisting of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and zircon calcium (CaZrO₃), but its material is not limited thereto, and may include a metal material and/or an organic material.

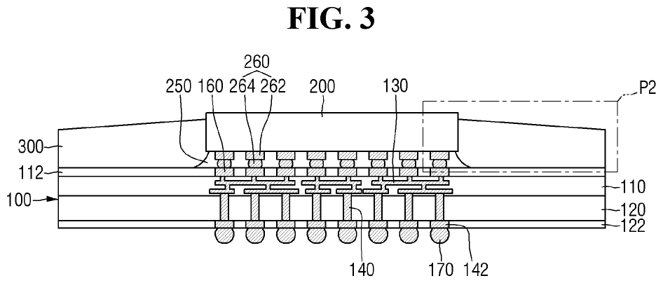

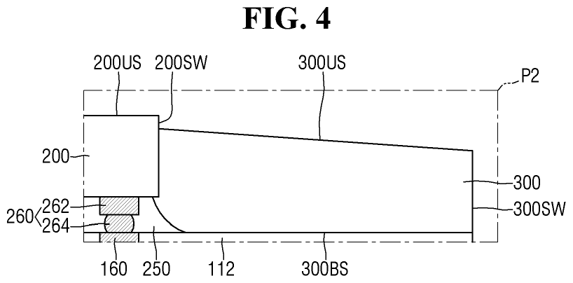

FIG. 3 is a view illustrating a semiconductor package according to some other embodiments. FIG. 4 is an enlarged view illustrating a portion P2 of FIG. 3. For convenience of description, the following description will be based on differences from the description made with reference to FIGS. 1 and 2.

Referring to FIGS. 3 and 4, the upper surface 300US of the molding layer may have an inclined cross-section. Between the side of the first semiconductor chip 100 and the side of the second semiconductor chip 200, the height of the upper surface 300US of the molding layer may not be constant and can be variable or sloped with respect to the upper surface of the first semiconductor chip 100. Between the side of the first semiconductor chip 100 and the side of the second semiconductor chip 200, the height of the upper surface 300US of the molding layer may change with respect to the upper surface of the first semiconductor chip 100.

The height of the upper surface 300US of the molding layer in an area that is in contact with the side 200SW of the second semiconductor chip, may be different from the height of the upper surface 300US of the molding layer along the side 300SW of the molding layer. The height of the upper surface of the molding layer 300 may be lowered as the molding layer 300 approaches the side of the first semiconductor chip 100 from the side 200SW of the second semiconductor chip. The height of the upper surface 300US of the molding layer in an area that is in contact with the side 200SW of the second semiconductor chip 200 may be greater than the height of the upper surface 300US of the molding layer along the side 300SW of the molding layer from the lower surface 300BS of the molding layer.

The upper surface 300US of the molding layer may be the highest at a point that is in contact with the side 200SW of the second semiconductor chip. The upper surface 200US of the second semiconductor chip may be above the upper surface 300US of the molding layer. For example, the height of the upper surface 200US of the second semiconductor chip may be greater than the height of the upper surface 300US of the molding layer, which is in contact with the side 200SW of the second semiconductor chip with respect to the lower surface 300BS of the molding layer.

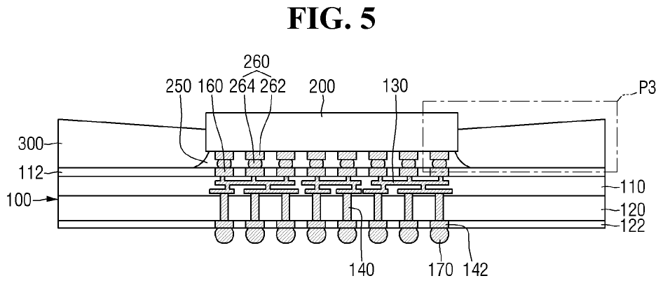

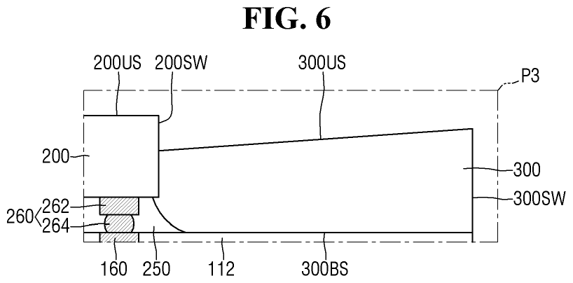

FIG. 5 is a view illustrating a semiconductor package according to some other embodiments. FIG. 6 is an enlarged view illustrating a portion P3 of FIG. 5. For convenience of description, the following description will be based on differences from the description made with reference to FIGS. 1 to 4.

Referring to FIGS. 5 and 6, the upper surface 300US of the molding layer may have an inclined cross-section. Between the side of the first semiconductor chip 100 and the side 200SW of the second semiconductor chip, the height of the upper surface 300US of the molding layer may not be constant and be variable or sloped with respect to the upper surface of the first semiconductor chip 100. Between the side of the first semiconductor chip 100 and the side of the second semiconductor chip 200, the height of the upper surface 300US of the molding layer 300 may be changed (e.g., variable or sloped) with respect to the upper surface of the first semiconductor chip 100.

The height of the upper surface 300US of the molding layer in an area that is in contact with the side 200SW of the second semiconductor chip, may be different from the height of the upper surface 300US of the molding layer along the side 300SW of the molding layer. The height of the upper surface of the molding layer 300 may increase as the molding layer 300 approaches the side of the first semiconductor chip 100 from the side 200SW of the second semiconductor chip. The height of the upper surface 300US of the molding layer 300 in an area that is in contact with the side 200SW of the second semiconductor chip may be lower than the height of the upper surface 300US of the molding layer 300 in along the side 300SW of the molding layer with respect to the lower surface 300BS of the molding layer.

The height of the upper surface 300US of the molding layer may be the highest at a point along the side 300SW of the molding layer. The upper surface 200US of the second semiconductor chip may be above the upper surface 300US of the molding layer. For example, the height of the upper surface 200US of the second semiconductor chip may be greater than the height of the upper surface 300US of the molding layer at the point along the side 300SW of the molding layer with respect to the lower surface 300BS of the molding layer.

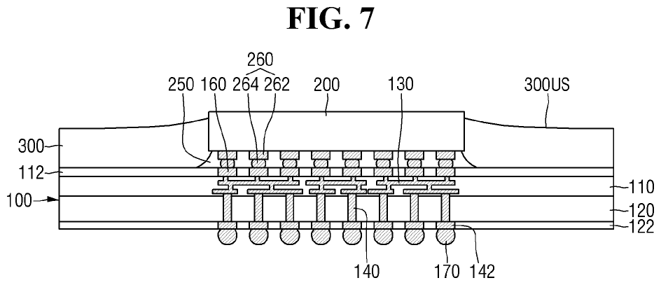

FIG. 7 is a view illustrating a semiconductor package according to some other embodiments. For convenience of description, the following description will be based on differences from the description made with reference to FIGS. 1 and 2.

Referring to FIG. 7, the upper surface 300US of the molding layer may not be flat or planar. The upper surface 300US of the molding layer may be curved. The upper surface 300US of the molding layer may have a curved cross-section. For example, the upper surface 300US of the molding layer may be recessed downward toward the first semiconductor chip 100.

FIG. 7 illustrates that the upper surface 300US of the molding layer is recessed toward the first semiconductor chip 100, but the embodiment is not limited thereto. For example, the upper surface 300US of the molding layer may have an upwardly convex cross-section.

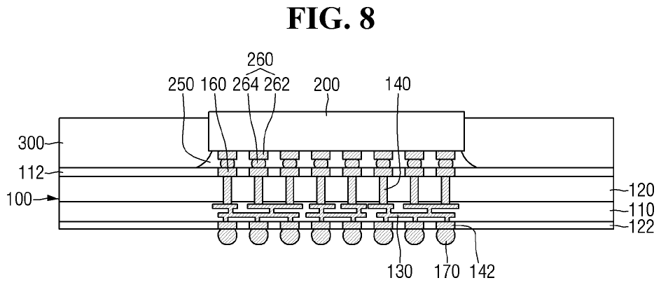

FIG. 8 is a view illustrating a semiconductor package according to some other embodiments. For convenience of description, the following description will be based on differences from the description made with reference to FIGS. 1 and 2.

Referring to FIG. 8, the first semiconductor substrate 120 may be on the first semiconductor device layer 110. The first semiconductor device layer 110 may be spaced apart from the second semiconductor chip 200 with the first semiconductor substrate 120 interposed therebetween.

The upper passivation film 112 may be on the first semiconductor substrate 120. The upper passivation film 112 may extend along the upper surface of the first semiconductor substrate 120. The lower passivation film 122 may be below the first semiconductor device layer 110. The lower passivation film 122 may extend along the lower surface of the first semiconductor device layer 110.

The through via 140 may be on the first wiring structure 130. The through via 140 may be more adjacent to the second semiconductor chip 200 than the first wiring structure 130. The through via 140 may be connected to the first upper connection pad 160. The through via 140 may be in contact with the first upper connection pad 160.

The first wiring structure 130 may be spaced farther apart from the second semiconductor chip 200 than the through via 140. The first wiring structure 130 may be between the through via 140 and the first connection bumps 170

The first lower connection pad 142 may be below the first semiconductor device layer 110. The first lower connection pad 142 may be electrically connected to the first wiring structure 130 inside the first semiconductor device layer 110. The first lower connection pad 142 may be electrically connected to the through via 140 through the first wiring structure 130.

The first upper connection pad 160 electrically connected to the through via 140 may be formed on the upper surface of the first semiconductor substrate 120. The first upper connection pad 160 may be made of the same material as that of the first lower connection pad 142. The first upper connection pad 160 may be inside the upper passivation film 112. The first upper connection pad 160 may be surrounded by the upper passivation film 112.

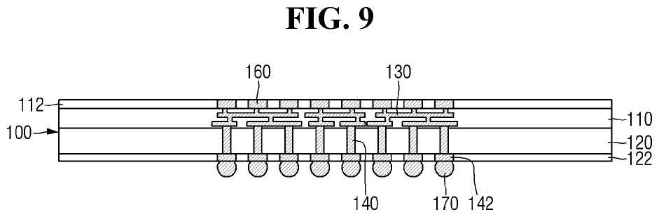

FIGS. 9 to 13 are views illustrating intermediate steps to describe a method for fabricating a semiconductor package according to some embodiments.

Referring to FIG. 9, the first semiconductor chip 100 may be formed.

The first semiconductor device layer 110 may be formed on the first semiconductor substrate 120. The upper passivation film 112 and the first upper connection pad 160 may be formed on the first semiconductor device layer 110. The lower passivation film 122, the first lower connection pad 142 and the first connection bumps 170 may be formed on the lower surface of the first semiconductor substrate 120.

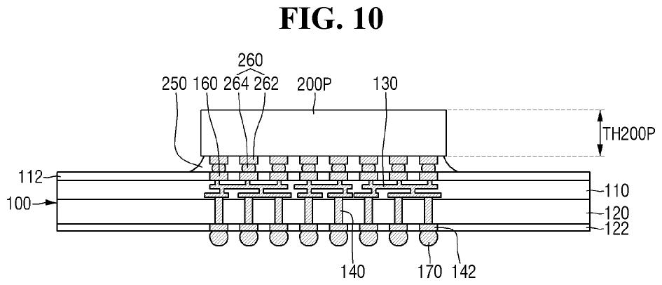

Referring to FIG. 10, a second pre-semiconductor chip 200P may be formed.

The second pre-semiconductor chip 200P may have a first thickness TH200P. The first thickness TH200P may refer to a distance between a lower surface and an upper surface of the second pre-semiconductor chip 200P.

The second pre-semiconductor chip 200P may be formed on the first semiconductor chip 100. The second pre-semiconductor chip 200P may be formed to be electrically connected to the first wiring structure 130 through the second connection bumps 260. The second pre-semiconductor chip 200P may be attached onto the first semiconductor chip 100 through the underfill 250.

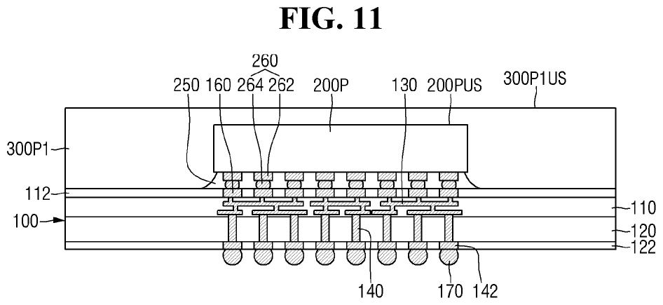

Referring to FIG. 11, a first pre-molding layer 300P1 may be formed.

The first pre-molding layer 300P1 may be formed on the first semiconductor chip 100. The first pre-molding layer 300P1 may cover the second pre-semiconductor chip 200P. The first pre-molding layer 300P1 may surround or be on the second pre-semiconductor chip 200P. The first pre-molding layer 300P1 may cover an upper surface 200PU of the second pre-semiconductor chip 200P.

An upper surface 300P1US of the first pre-molding layer may be above the upper surface 200PUS of the second pre-semiconductor chip. A height of the upper surface 300P1US of the first pre-molding layer may be greater than that of the upper surface 200PUS of the second pre-semiconductor chip with respect to the upper surface of the first semiconductor chip 100. The upper surface 200PUS of the second pre-semiconductor chip may not be exposed by the first pre-molding layer 300P1.

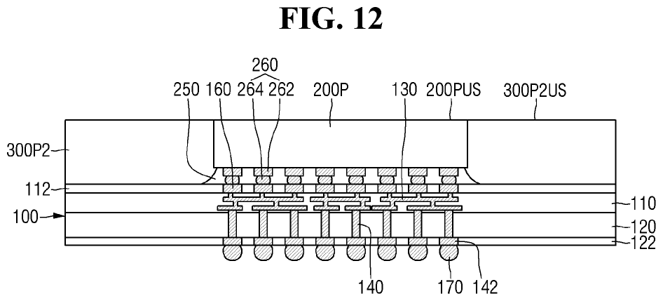

Referring to FIG. 12, an upper portion of the first pre-molding layer (300P1 of FIG. 11) may be partially removed to form a second pre-molding layer 300P2.

A height of an upper surface 300P2US of the second pre-molding layer 300P2 may be equal to that of the second pre-semiconductor chip 200P. The upper surface 300P2US of the second pre-molding layer may be on the same plane as the upper surface 200PUS of the second pre-semiconductor chip. The upper surface 200PUS of the second pre-semiconductor chip may be exposed by or free from contact with the second pre-molding layer 300P2.

The upper portion of the first pre-molding layer (300P1 of FIG. 11) may be partially removed through a grinding process. When the grinding process is performed, a scratch or scratches may be generated on the upper surface 200PUS of the second pre-semiconductor chip.

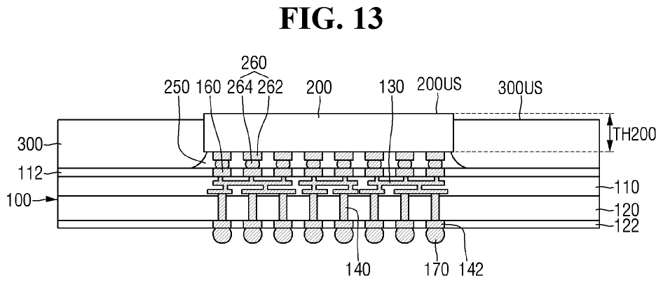

Referring to FIG. 13, an upper portion of the second pre-semiconductor chip (200P of FIG. 12) may be partially removed to form the second semiconductor chip 200. An upper portion of the second pre-molding layer (300P2 of FIG. 12) may be partially removed to form the molding layer 300.

The second semiconductor chip 200 may have a second thickness TH200. The second thickness TH200 may be a distance between the lower surface and the upper surface 200US of the second semiconductor chip 200. The second thickness TH200 may be smaller than the first thickness (TH200P in FIG. 10). The upper surface 300US of the molding layer may be below the upper surface 200US of the second semiconductor chip.

The second semiconductor chip 200 and the molding layer 300 may be formed through a chemical mechanical polishing (CMP) process. That is, the upper portion of the second pre-semiconductor chip (200P of FIG. 12) and the upper portion of the second pre-molding layer (300P2 of FIG. 12) may be simultaneously removed by the CMP process. When the CMP process is performed, the second pre-molding layer (300P2 of FIG. 12) may be more removed than the second pre-semiconductor chip (200P of FIG. 12) due to a difference in polishing speed between the second pre-semiconductor chip (200P of FIG. 12) and the second pre-molding layer (300P2 of FIG. 12). Therefore, the upper surface 300US of the molding layer may be formed below the upper surface 200US of the second semiconductor chip.

As the upper portion of the second pre-semiconductor chip (200P of FIG. 12) is removed, the scratch(es) generated on the upper surface (200PUS of FIG. 12) of the second pre-semiconductor chip may be removed through the above grinding process. Therefore, a surface roughness of the upper surface of the second semiconductor chip 200 may be smaller than that of the upper surface (200PUS of FIG. 12) of the second pre-semiconductor chip. The second semiconductor chip 200 in which the scratch(es) generated on the upper surface is removed and the surface roughness is reduced may have enhanced mechanical properties. For example, cracks may not easily occur in the second semiconductor chip 200 due to external impact.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor package comprising:
a first semiconductor chip;
a second semiconductor chip on the first semiconductor chip;
at least one connection bump between the first semiconductor chip and the second semiconductor chip;
an underfill in a region below the second semiconductor chip and on a side of the at least one connection bump; and
a molding layer on the first semiconductor chip and on a side of the second semiconductor chip,
wherein an upper surface of the second semiconductor chip is above an upper surface of the molding layer,
a height difference between the upper surface of the second semiconductor chip and the upper surface of the molding layer is 0.3 μm to 2.0 μm, and
a surface roughness of the upper surface of the second semiconductor chip is 3 nm or less.

2. The semiconductor package of claim 1, wherein each of the first semiconductor chip and the second semiconductor chip is a logic chip.

3. A semiconductor package comprising:
a first semiconductor chip;
a second semiconductor chip on the first semiconductor chip; and
a molding layer on the first semiconductor chip and on a side of the second semiconductor chip,
wherein an upper surface of the second semiconductor chip is above an upper surface of the molding layer by 0.3 μm to 2.0 μm.

4. The semiconductor package of claim 3, wherein a side of the molding layer is on a same plane as a side of the first semiconductor chip.

5. The semiconductor package of claim 3, wherein a surface roughness of the upper surface of the second semiconductor chip is 3 nm or less.

6. The semiconductor package of claim 3, wherein each of the first semiconductor chip and the second semiconductor chip is a logic chip.

7. The semiconductor package of claim 3, further comprising an underfill on the first semiconductor chip and in a region below the second semiconductor chip.

8. The semiconductor package of claim 3, wherein the first semiconductor chip includes a through via and a wiring layer connected to the through via,
the wiring layer faces the second semiconductor chip, and the through via is below the wiring layer.

9. The semiconductor package of claim 3, wherein the first semiconductor chip includes a through via and a wiring layer connected to the through via,
the through via is connected to the second semiconductor chip, and the wiring layer is below the through via.

10. The semiconductor package of claim 3, wherein the upper surface of the molding layer is planar.

11. The semiconductor package of claim 3, wherein a height of the upper surface of the molding layer is variable with respect to the upper surface of the first semiconductor chip in an area between the side of the second semiconductor chip and a side of the molding layer.

12. The semiconductor package of claim 3, wherein a width of the first semiconductor chip is greater than a width of the second semiconductor chip.

13. A semiconductor package comprising:
a first semiconductor chip;
a second semiconductor chip on the first semiconductor chip; and
a molding layer on the first semiconductor chip and on a side of the second semiconductor chip,
wherein the second semiconductor chip includes a first portion that overlaps the molding layer and a second portion that is on the first portion and does not overlap the molding layer, and
an upper surface of the molding layer is lower than an upper surface of the second semiconductor chip.

14. The semiconductor package of claim 13, wherein the upper surface of the molding layer is curved.

15. The semiconductor package of claim 13, wherein a height of a sidewall of the first portion is 0.3 μm to 2.0 μm with respect to the upper surface of the molding layer.

16. The semiconductor package of claim 13, wherein a surface roughness of the upper surface of the second semiconductor chip is 3 nm or less.

17. The semiconductor package of claim 13, wherein silicon is on the upper surface of the second semiconductor chip.

18. The semiconductor package of claim 13, further comprising at least one external connection bump on a lower surface of the first semiconductor chip and electrically connected to the first semiconductor chip.

19. The semiconductor package of claim 13, further comprising an underfill on the first semiconductor chip and in a region below the second semiconductor chip.

20. The semiconductor package of claim 13, wherein a width of the first semiconductor chip is greater than a width of the second semiconductor chip.
